(19) United States
(12) Patent Application Publication
(10) Pub. No.: US 2026/0308747 A1
(43) Pub. Date: Oct. 8, 2026

(54) WNiX SPUTTERING TARGET

(71) Applicants: PLANSEE SHANGHAI HIGH PERFORMANCE MATERIAL LTD, SHANGHAI (CN); PLANSEE SE, REUTTE (AT)

(72) Inventors: THOMAS SCHERER, REUTTE (AT); YONGYUE CAI, SHANGHAI (CN); CHRISTIAN LINKE, REUTTE (AT); HENNRIK SCHMIDT, REUTTE (AT); YI SUN, SHANGHAI (CN)

(21) Appl. No.: 19/485,007

(22) PCT Filed: Apr. 19, 2024
(86) PCT No.: PCT/CN2024/088902

§ 371 Date: Nov. 17, 2025

(30) Foreign Application Priority Data
May 16, 2023 (CN) 202310549498.6

(51) Int. Cl. C23C 14/34

(52) U.S. Cl. CPC C23C 14/3414

(57) ABSTRACT

A sputtering target is produced by powder metallurgy. The sputtering target is formed of tungsten (W), nickel (Ni) and one further metal X selected from group 5 or group 6 of the periodic table of elements, as well as inevitable impurities. The sputtering target has a two-phase microstructure, wherein one phase is pure W and the other phase is a mixed phase selected from the group of NiWX, NiW, NiX and mixtures thereof. There is also described a process for producing a WNiX sputtering target via the powder-metallurgical route.

### TECHNICAL FIELD

The present invention relates to a WNiX sputtering target produced by powder metallurgy, wherein X is selected from the group consisting of group 5 or group 6 of the periodic table. The invention further relates to a process for producing a WNiX sputtering target via the powder-metallurgical route.

### BACKGROUND

Sputtering, also referred to as cathode atomization, is a physical process in which atoms are detached from a sputtering target by bombardment with high-energy ions and go over into the gas phase.

Sputtering targets which are composed of Ni, W and optionally, one or more further metal(s) X selected inter alia from the group of the refractory metals, especially NiWCr and NiWTa, are already known from the prior art.

However, a problem of the prior art is that the use of a Ni powder as starting material for making the targets has the consequence that pure nickel, which displays ferromagnetic properties, is present in the target material. This means that a ferromagnetic pure Ni fraction or Ni phase occurs in the microstructure of such sputtering targets. The ferromagnetic properties are disadvantageous for magnetron sputtering since they result in different and unstable coating rates and thus have a disadvantageous influence on the homogeneity of a possible deposited layer to be formed. Compared to the above-mentioned “simple” cathode atomization in the case of magnetron sputtering a magnetic field is additionally generated. The superposition of an electric field and a magnetic field lengthens the path of the charge carriers and increases the number of impacts per electron. For example, EP 3 825 427 A1 relates to a sputtering target comprising Ni, W and, optionally one or more further metals(s) X selected from the group of refractory metals (e.g., Ti, V, Cr, Mn, Zr, Nb etc.), Sn, Al, and Si. In this application the sputtering target has a normalized peak intensity ratio of 0.40 or greater comprising a fraction of pure Ni.

CN 104 646 930 A relates to a method for manufacturing a NiWCr alloy target comprising the steps of melting, casting, forging, primary heat treating, hot rolling, cold rolling and secondary heat treating. CN 102 534 308 A discloses a NiWCr alloy target having the composition 15-35 wt. % W and 5 -15 wt. % Cr. Also this material is prepared by the steps of melting, casting, hot forging, cold rolling and recrystallization annealing. JP 2010-133001 A teaches a method of manufacturing a Ni alloy target containing 10 to 30% by mass of one or more selected from (Cr, Mo, W), balance being Ni, wherein the target is obtained by melting, casting, subjecting to plastic working and recrystallization treatment. However, sputtering targets produced by melt metallurgy show the disadvantage of a coarse microstructure after the casting step which leads to relief formation in the sputtering process through inhomogeneous erosion. This problem can be counteracted by a powder metallurgy production route. Sputtering targets produced by powder metallurgy show a very homogenous fine-grain microstructure after sintering which subsequently ensures homogeneous erosion in the course of sputtering and an optimized thin layer. Although some of the above-mentioned patent applications mention a fine and uniform grain size in the target this grain sizes are achieved by additional production steps after casting.

WO 2010/009829 discloses a sputtering target being made of an NiWCr alloy containing 1-20 at. % W and 1-20 at. % Cr, remainder Ni. This sputtering target can be either produced by casting or by a powder-metallurgical production. However, this document is silent regarding the microstructure of the alloy target. Accordingly, it is not evident whether fraction of pure Ni is present in the microstructure of the sputtering target.

JP 2009-155722 A teaches a sintered target material containing 3 to 15 at. % W, 20 at. % Cr or less and the balance being Ni. The microstructure is described as a face-centered cubic structure. The present application provides a sputtering target having more than 15 at. % W. The sputtering targets described in the prior art do not meet the increasing requirements in respect to layer homogeneity, homogeneity of the sputtering behaviour and avoidance of undesired local partial melting. Local partial melting is caused, for example, by arc processes (local formation of an electric arc).

### SUMMARY

The object of the present invention is to provide a WNiX sputtering target by means of which a very homogeneous layer, both in respect to chemical composition and in respect to of layer thickness distribution, can be produced, wherein the microstructure is free from pure (or elementary) Ni-phases. In addition, the sputtering target should have a uniform sputtering behaviour. Here, uniform sputtering behaviour means that the individual phases in the microstructure of the sputtering target can be ablated at the same rate.

It is further an object of the present invention to provide production route for manufacturing of a WNiX sputtering target which has the abovementioned properties in a simple and reproducible and also inexpensive way.

The object is achieved by the independent claims. Advantageous embodiments are indicated in the dependent claims.

A sputtering target according to the invention comprises tungsten (W), nickel (Ni), one further metal X selected from the group consisting of group 5 or group 6 of the periodic table and inevitable impurities. It is characterized in that the microstructure shows a two-phase microstructure, wherein one phase is pure W (i.e., W grains) and the other phase is a mixed phase selected from the group of NiWX, NiW, NiX and mixtures thereof measured at a cross section of the target material.

For the purposes of the present invention, “microstructure” means the microstructure of the sputtering target, which can be analysed in a simple manner with which a person skilled in the art will be familiar with the aid of a metallographic polished section and assessment under an optical microscope or scanning electron microscope.

The occurrence of the pure W-phase as well as the mixed phases in a sputtering target according to the invention can very easily be confirmed or ruled out by means of X-ray diffraction (XRD) (taking into account the respective X-ray detection limit) using JCPDS (Joint Committee on Powder Diffraction Standards) cards. The mixed phases refer to phases which occur in binary or ternary component systems which are different from the pure components used as starting elements. They frequently have crystal structure which deviate from the crystal structure of the pure components and the mixed phase is characterized by a composition having inexact (meaning not directly corresponding to the valencies of the pure component) valency.

Two-phase microstructure of the sputtering target refers to the occurrence of a pure W-phase and a mixed phase, but further additional phases such as oxides or pores can also be present therein. However, the proportion of such further phases should be as small as possible since they can have a negative effect on the sputtering behaviour, in particular the homogeneity thereof. Thus, oxides can, for example, promote the occurrence of local incipient melting (arcing).

The occurrence of mixed phases is not disadvantageous in respect of the magnetic properties of a sputtering target according to the invention since Ni-containing phases, i.e., NiWX, NiW or NiX, occurring in the WNiX system are not ferromagnetic.

The term “inevitable impurities” refers to production-related contamination with gases or accompanying elements which originate from the raw materials used. The proportion of such impurities in a sputtering target according to the invention is preferably in the range below 350 μg/g (corresponding to ppm) for gases (C, H, N, O) and below 300 μg/g for other elements (e.g., Al, Ca, Cd, Cu, Fe, K, Li, Mg, Mn, Na, P, Pb, S, Zr). Suitable methods of chemical elementary analysis are known to be dependent on the chemical element to be analysed. Chemical analysis of the inevitable impurities according to the invention was carried out by hot extraction analysis for the elements O, N and H or by combustion analysis for the elements C and S or by using ICP-MS (inductively coupled plasma mass spectrometry) or ICP-OES (optical emission spectroscopy with inductively coupled plasma).

The chemical analysis of the main components W, Ni and X in the sputtering target material according to the invention was carried out using XRF (X-ray fluorescence analysis).

In a preferred embodiment of the invention, the other metal X is one metal selected from the elements Cr, Mo, Nb or Ta, more preferably the other metal X is Cr or Ta.

The high electrical conductivity, especially of molybdenum, tungsten, tantalum, niobium and chromium is advantageous for use as conductor track. The low coefficient of thermal expansion, especially of molybdenum, tungsten, tantalum, niobium and chromium, ensures good adhesion of the layer and low layer stresses when deposited on a substrate.

Preferably the sputtering target according to the invention comprises 38-70 wt. % W, 25-50 wt. % Ni, 5-22 wt. % X and a maximum proportion of inevitable impurities of ≤650 μg/g. It is evident to the skilled person that the sum of W+Ni+X+impurities amounts to 100 wt. %. If the amount of W is less than 38 wt. % W it is possible that ferromagnetic Ni phases occur in the sputtering target. If the W-content is higher than 70 wt. %, the hardness of the target material is too high in order to be able to ensure optimal and economical processability. At the above-mentioned W-content of 38-70 wt. % the occurrence of a mixed phase consisting of a NiWX phase, optionally a NiW phase, optionally a NiX phase or optionally mixtures thereof, is greatly favoured. A preferred composition of the sputtering target comprises 40-67 wt. % W, 26-46 wt. % Ni, 6-21 wt. % X. Preferably, a maximum proportion of inevitable impurities according to the invention is ≤300 μg/g. Also in this case it is evident that the sum of W+Ni+X+impurities amounts to 100 wt. %.

The sputtering target according to the invention preferably has a relative density of more than 85%. A relative density of more than 90% is particularly advantageous. The density of the sputtering target is highly dependent on the element X in the WNiX target and especially of the O-content in the powder of the element X. The higher the density of the target, the more advantageous are its properties. Targets having a low relative density have a relatively high proportion of pores which can be a virtual leak and/or a source of impurities and particles during the sputtering process. In addition, targets having a low density tend to absorb water or other impurities, which can lead to difficult-to-control process parameters. In addition, the ablation rate of material which is densified to only a low extent is lower during the sputtering process than that of material having a higher relative density.

The absolute density can, as it is known, easily be determined by means of buoyancy methods using the Archimedes principle. The relative density can be determined by e.g., a micrograph.

A sputtering target according to the invention preferably has an oxygen content of less than 350 μg/g, preferably less than 100 μg/g, more preferably less than 75 μg/g, even more preferably less than 30 μg/g. By having such a low oxygen content undesirable arc processes during sputtering can be reliably avoided.

The oxygen content can be determined in a simple way by hot extraction analysis.

A sputtering target according to the invention is characterized by a hardness which is preferably below 400 HV 10 after the steps of pressing and sintering. It has been found that satisfactory toughness of the target material can optimally be ensured at hardness's of less than 400HV 10. This simplifies handling during the production process, for example during an optional mechanical shaping step. During use, especially as single-piece tubular target in one embodiment, a hardness of less than 400 HV 10 significantly simplifies handling. The hardness of the sputtering target according to the invention can be increased up to 600 HV 10 by carrying out one or more forming steps after pressing and sintering.

The hardness in HV10 (Vickers hardness) is for the present purposes an arithmetic mean determined from 5 hardness measurements.

The installation of a sputtering target according to the invention in various coating plants and also for the coating of substrates having different geometries places various geometric demands on a sputtering target according to the invention. Thus, a target of this type can be in the form of a flat sputtering target, for example as plate or disc, or in the form of a tubular sputtering target. Also, additional target forms may be in the scope of the present invention, e.g., a rod or a body having another complex shape.

A sputtering target according to the invention can be a multipart sputtering target or a one-piece sputtering target.

Regarding the design as a one-piece tubular sputtering target, this enables particularly homogeneous layers to be deposited on large-area substrates since no discontinuities (for example joins, undercuts, residues of solder material, impurities in the region of a join) between individual pieces (segments) of a target are present.

The design as one-piece tubular target makes it possible to avoid shifting of individual pieces of the target due to different temperatures or temperature cycles during the coating process, in contrast to multipart tubular targets. In addition, the homogeneity of the target material in respect of the chemical purity or the microstructure is better in the case of one-piece tubular targets than in the case of multi-part tubular targets.

However, a sputtering target according to the invention can be configured not only as one-piece tubular target. As already mentioned above, it can also be present as multipart tubular target or have various regions having different external diameters or relative densities over its length (“dog bone” target). Such an embodiment enables, for example, nonuniform ablation of the sputtering target at the ends of the target material (“cross-corner effect”) to be reduced or be largely avoided. A target having regions of different diameters can also be constructed in both one piece and as a multipart target.

A sputtering target according to the invention preferably has a proportion by area of W phase measured on a cross section of the target material in the range from 5% to 50%, preferably from 15% to 45%.

A proportion by area of W phase of less than 5% can be associated with an increased proportion of a ferromagnetic Ni phase and accordingly lead to a poor sputtering behaviour. Proportions by area of W phase of greater than 50% can have an adverse effect on the hardness of the target material and the processability.

The proportion of area of W phase is determined by suitable evaluation of a metallographic polished section. A metallographic polished section is a two-dimensional section of the three-dimensional target material. Areal analyses can be carried out by means of commercially available image analysis software on micrographs produced in this way. This is carried out by image analysis in order to determine proportions of individual phases in the abovementioned microstructure, typically by contrasting of the phases to be distinguished. The average proportion by area is calculated as arithmetic mean of 5 measurements of the proportion by area measured on 5 image regions having a size of 600×500 μm of a metallographic polished section, recorded with 200:1 magnification.

A sputtering target according to the invention preferably has an average grain size of the W phase of less than 40 μm, more preferably less than 30 μm.

An average grain size of the W phase of less than 40 μm, more preferably less than 30 μm, leads to a particularly uniform sputtering behaviour and thus to deposition of particularly homogeneous layers having a particularly uniform thickness. In addition, the notch effect of the W phase is kept low in this way and satisfactory toughness of the target material is optimally ensured as a result.

Agglomerates of a plurality of grains of the W phase can exceed dimensions of 40 μm in diameter, but such agglomerates are not considered to be individual grains of the W phase in a sputtering target according to the invention.

The average grain size of the W phase can be determined in a simple way by a line section method, for example as indicated in ASTM E112-12, on a metallographic polished section. A process according to the invention for producing a WNiX sputtering target via the powder-metallurgical route is characterized in that it comprises at least the following steps: a compacting step in which a powder mixture of W powder, Ni powder and X powder is compacted by application of pressure, heat or pressure and heat to give a blank.

A compacting step as part of a process according to the invention for producing a WNiX sputtering target leads to an appropriate powder mixture being compacted and densified by application of pressure, heat or pressure and heat to form a blank. This can occur by means of various process steps, for example by pressing and sintering, cold isostatic pressing, hot isostatic pressing, hot pressing, or spark plasma sintering (SPS) or a combination of these methods or further methods of compacting powder mixtures.

The production of a powder mixture which can be used for a process according to the invention is preferably achieved by mixing the appropriate amounts of W powder, Ni powder and X powder. These powders are filled into a suitable mixing apparatus and mixed until homogeneous distribution of the components in the powder mixture is ensured. For the purposes of the present invention, the expression powder mixture may include pre-alloyed or partially alloyed powders containing the components W, Ni and X.

In a preferred embodiment mixing of the powders is carried out in an inert atmosphere, for example by using the inert gases argon or nitrogen.

The powder mixture produced in such a way is preferably introduced into a mould in order to implement the compacting step. Suitable moulds here are the die or flexible tube of a cold isostatic press, the die of a hot press or a spark plasma sintering plant, or else the can in the case of hot isostatic pressing.

It has been found to be particularly advantageous for the compacting step to be effected by sintering at temperatures of from 1100 to 1450° C. in a process according to the invention for producing a WNiX sputtering target. Preferably the sintering temperatures are within the range of 1250 to 1400° C. Here, sintering is a sintering process referred to as pressure-less sintering at pressures of less than 2 MPa, preferably at pressures below atmospheric pressure.

Compaction at these temperatures optimally ensures that solid-phase sintering or liquid phase sintering to very high relative densities take place in the powder mixture present. At compaction at below 1100° C., the achievable density can be too low, while at temperatures above 1450° C. reductions in the mechanical stability of the target material can occur. In the case of compaction in the temperature ranges indicated, an optimal combination of high achieved density and optimal mechanical properties is ensured and a low oxygen content can be achieved.

Sintering is advantageously carried out under vacuum, in an inert atmosphere and/or reducing atmosphere. For the present purpose, an inert atmosphere is a gaseous medium which does not react with the alloy components, for example a noble gas. A suitable reducing atmosphere is, in particular, hydrogen.

The blank obtained by a process according to the invention can subsequently subjected to a forming step in order to possibly produce advantageous properties such as a further increase in the density and/or further homogenization of the microstructure. Suitable processes for carrying out a forming step for the purposes of the present invention are, for example, rolling, extrusion, and forging. Preferably rolling or forging is used as suitable forming step.

A forming step for the purposes of the present invention can be carried out as a single-stage or multistage process. A combination of a plurality of suitable processes is also possible. Thus, a forming treatment can contain one or more substeps.

Defined degrees of deformation can be introduced into the target material in a particularly purposeful way by a forming treatment containing at least one forging step or rolling step. In this way, excessive strengthening, for example, and consequently exceeding of the deformation forces which can be applied can be avoided thereby.

Textures can be introduced into the target material in a purposeful way by means of a forming treatment containing at least one rolling step or forging step and these can in turn exert a positive influence both on the mechanical properties and on the sputtering properties of the target material.

Furthermore, by using one or more rolling step(s) or forging steps make(s) it possible to vary the thickness of the formed material over its length and set this thickness in a purposeful manner. The thickness can be utilized, in particular, for increasing the sputtering yield (regions having different external diameters over the length, “dog bone” target).

In addition, it is possible by the means of rolling to achieve a uniform surface quality which is favourable for further mechanical processing, straightness and good roundness can be achieved by means of forging or rolling.

A process for producing a sputtering target according to the invention can further comprise the following step:
heat treatment

Both after compaction by pressure, heat or pressure and heat and after any forming step performed, heat treatment of the blank may be advantageous. According to the chemical composition of the sputtering target the temperatures employed may be within a range of from 1000 to 1200° C. Moreover, the effect of such heat treatment may go from an exclusive dissipation of stresses as far as changes in microstructure through movement of small-and/or large-angle grain boundaries.

A mechanical processing of the blank or target material obtained can be desirable or necessary after the compacting step, after an optional forming step or after an optional heat treatment step. Such a mechanical treatment, for example by cutting machining, grinding or polishing, enables both the final geometry to be set or made more precise and, for example, a particular desirable surface quality to be set. These processing steps can be configured either as dry or wet processing steps.

A sputtering target produced by a process according to the invention can also be applied to one or more suitable support elements by means of, for example a bonding step. Such support elements can, for example, be backing plates of various geometries or in the preferred case of a tubular sputtering target, in particular a one-piece tubular target, can be a support tube or else support elements which do not run through the entire tube, e.g., ports, flanges or other connecting parts or multipart support tubes or elements.

Such support elements can, for example, be made of stainless steel, Cu, Cu alloys, Ti or Ti alloys. However, other materials can also be used for producing such support elements.

For a bonding step, preference is given to using elements or alloys having a low melting point, for example indium. In addition, a bonding agent, for example Ni, can optionally be used in order to ensure better wetting. Instead of a bonding step, the application to suitable support elements can also be carried out by means of soldering or adhesive bonding or by mechanical locking, for example by screwing-on or clamping.

The application of a corrosion-resistant protective facility, for example in the form of paint or varnish or in the form of a polymer coating, to at least parts of the internal diameter of the target material is also possible as further step in a process according to the invention for producing a WNiX sputtering target.

In a preferred case, a sputtering target containing 38-70 wt. % W, 25-50 wt. % Ni, 5-22 wt. % X, and a maximum proportion of inevitable impurities of ≤650 μg/g is produced by means of a process according to the invention for producing a WNiX sputtering target. In this case, use of the process of the invention ensures that the microstructure of the WNiX sputtering target has two phases, wherein one phase is a pure W phase and the other phase is a mixed phase selected from the group of NiWX, NiW, NiX and mixtures thereof (measured by XRD).

A process according to the invention for producing a W-NiX sputtering target makes it possible to ensure relative densities of more than 85% in a WNiX sputtering target produced by this process. In particularly preferred embodiments of the invention, relative densities of more than 90% can be achieved.

The purity and the mechanical properties of the resulting target material are also optimized by a process according to the invention for producing a WNiX sputtering target.

Thus, a process according to the invention leads to very low contents of impurities in sputtering targets produced thereby, for example a preferred oxygen content of less than 350 μg/g, particularly preferably less than 100 μg/g, more preferably less than 75 μg/g, even more preferably less than 30 μg/g.

In a preferred case, a sputtering target containing from 38 to 70% by weight of W, 25 to 50% by weight Ni, from 5 to 22% by weight X and unavoidable impurities is produced by means of a process according to the invention for producing a WNiX sputtering target. In this case, hardnesses of less than 400 HV 10 are preferably achieved by means of a process according to the invention after the compacting step, e.g., pressing and sintering.

In a preferred case, a sputtering target containing from 38 to 70% by weight of W, 25 to 50% by weight Ni, from 5 to 22% by weight X and unavoidable impurities is produced by means of a process according to the invention for producing a WNiX sputtering target. In this case, a proportion by area of W phase measured at a cross section of the target material in the range from 5% to 50% is achieved by means of a process according to the invention. In a preferred case, a sputtering target containing from 38 to 70% by weight of W, 25 to 50% by weight Ni, from 5 to 22% by weight X and unavoidable impurities is produced by means of a process according to the invention for producing a WNiX sputtering target. In this case, an average grain size of the W phase of less than 40 μm, more preferably less than 30 μm, is achieved by means of a process according to the invention.

### BRIEF DESCRIPTION OF THE DRAWINGS

The figures show:

FIG. 1: X-ray diffraction pattern of a sample of a WNiMo sputtering target according to the invention;

FIG. 2: X-ray diffraction pattern of a sample of a WNiCr sputtering target according to the invention;

FIG. 3: Microstructure of a WNiMo sputtering target according to the invention (optical microscopy);

FIG. 4: Microstructure of a WNiCr sputtering target according to the invention (optical microscopy);

### DETAILED DESCRITPION

The invention is illustrated below with the aid of production examples and figures.

### EXAMPLES

### Example 1 (Production of a WNiMo Tube)

W metal powder having a particle size determined by the Fisher method of 4 μm, Ni metal powder having a particle size measured by the Fisher method of 4.2 μm, and Mo metal powder having a particle size measured by the Fisher method of 4.6 μm were used as raw materials. The powders were introduced in a ratio of 42 wt. % W, 47 wt. % Ni and 11 wt. % Mo into a closed vessel and mixed for 1 hour in a shaker.

A steel mandrel having a diameter of 141 mm was positioned in the middle of a rubber tub which had a diameter of 300 mm and was closed at one end. The powder mixture was introduced into the intermediate space between steel core and rubber wall and the rubber tube was closed at its open end by means of a rubber cap. The closed rubber tube was positioned in a cold isostatic press and pressed at a pressure of 200 MPa to give a green body in the form of a disc having a relative density of about 59% and an external diameter of 242 mm.

The green body produced in this way was sintered at a temperature of about 1250° C. in an indirect sintering furnace in a hydrogen atmosphere. The relative density after sintering was about 80%.

The hardness of the target material was 126HV 10 . An oxygen content of 190 μg/g was measured.

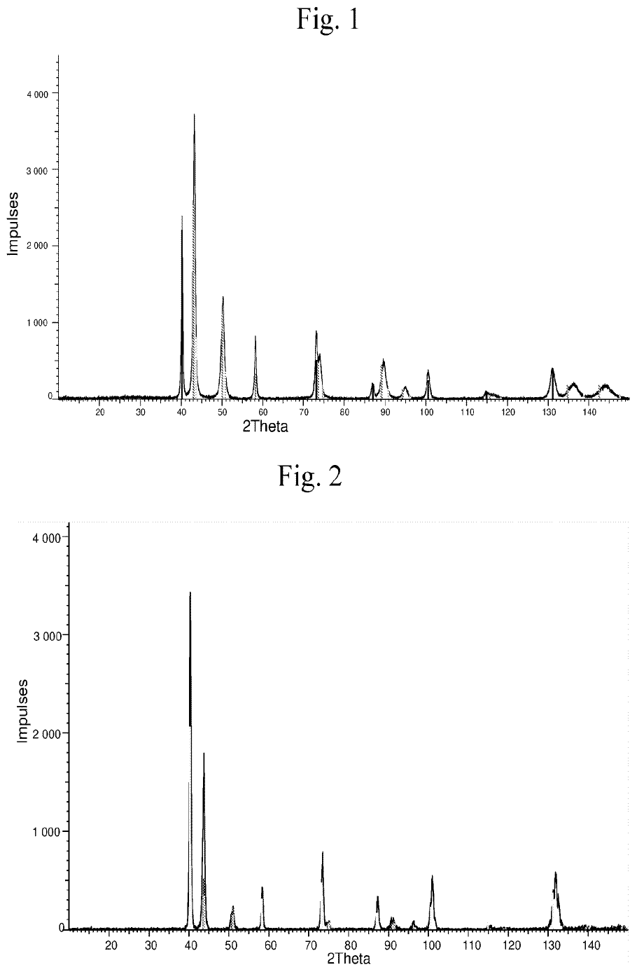

FIG. 1 shows the X-ray diffraction pattern of this Example. For the evaluation of the diffraction patterns, the JCPDS cards 00-004-0806 (W) (corresponding to the W-phase), 01-071-9764 (Mo1.08 Ni2.92), 01-072-2652 (Ni0.85 W0.15) (corresponding to the mixed phase) were used. From this Figure it is evident that no pure Ni phase (appearing at 2 Theta=44.5°) is present in the X-ray pattern. The peak at 2 Theta=40.2° refers to the pure W phase.

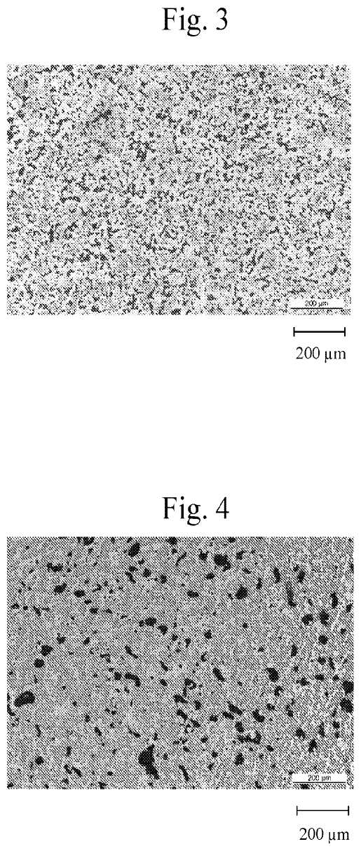

The microstructure is shown in FIG. 3 in an optical microscope image. For optical microscope images a specimen, for example a tube, is cut to approx. 15×15×15 mm³ and then placed into an embedding mould and filled with plastic granules. In the press, pressure and temperature are used to melt the granules; after cooling, the specimen is embedded in plastic. The surface to be examined is then polished with sandpaper from coarse to fine grit and finally with diamond suspension. Then the specimen is directly ready for examination under the optical microscope. W grains (dark grey colour) are located in a mixture of NiWMo (bright colour). The black colour shows the pores due the manufacturing via powder metallurgical route.

### Example 2 (Production of a WNiCr Plate)

Also in this case W metal powder having a particle size determined by the Fisher method of 4 μm, Ni metal powder having a particle size measured by the Fisher method of 4.2 μm, and Cr metal powder (sieved to less than 45 μm) were used as raw materials. The powders were introduced in a ratio of 67 wt. % W, 26 wt. % Ni and 7 wt. % Cr into a closed vessel and mixed for 1 hour in a shaker.

The powder mixture was introduced into a flexible rubber tube which was closed at its open end by means of a rubber cap. The closed rubber tube was positioned in a cold isostatic press and pressed at a pressure of 200 MPa to give a green body in the form of a plate having a relative density of about 64.9%.

The green body produced in this way was sintered at about 1400° C. for 4 hours in a hydrogen atmosphere in an indirect sintering furnace. The relative density after sintering was about 90%. The plate has the approximate dimensions of 268×48,7×343mm³ . The hardness of the target material was 189 HV10 and the oxygen content was 50 μg/g.

FIG. 2 shows the X-ray diffraction pattern of this Example. For the evaluation of the diffraction patterns, the JCPDS cards 00-004-0806 (W), 03-065-5108 (Cr₄Ni₁₅W), 01-071-7594 (CrNi), 03-065-6291 Cr₂Ni₃ and 01-077-3140 (Ni₉W)0.4 were used. From this Figure it is evident that no pure Ni phase (appearing at 2 Theta=44.5°) is present in the X-ray pattern. The peak at 2 Theta=40.2° refers to the pure W phase.

The microstructure is shown in FIG. 4 in an optical microscope image. A sample of this plate is prepared as explained in Example 1.

W grains (dark grey colour) are located in a mixture of NiWCr (bright colour). The black colour shows the pores due the manufacturing via powder metallurgical route.

1-15. (canceled)

16. A sputtering target, produced by powder metallurgy, the sputtering target comprising:
tungsten (W), nickel (Ni), a further metal X selected from group 5 or group 6 of the periodic table, and inevitable impurities;
the sputtering target having a two-phase microstructure, with one phase being pure W and an other phase being a mixed phase selected from the group consisting of NiWX, NiW, NiX, and mixtures thereof.

17. The sputtering target according to claim 16, wherein the further metal X is one metal selected from the group of elements consisting of Cr, Mo, Nb, and Ta.

18. The sputtering target according to claim 16, wherein the sputtering target has the following composition:
38-70. wt. % W;
25-50. wt. % Ni;
5-22. wt. % X; and
a maximum proportion of inevitable impurities of ≤650 μg/g; and
wherein a sum of W+Ni+X+impurities amounts to 100 wt. %.

19. The sputtering target according to claim 16, wherein a density of the sputtering target is at least 85%.

20. The sputtering target according to claim 16, wherein an oxygen content is less than 350 μg/g.

21. The sputtering target according to claim 20, wherein the oxygen content is less than 100 μg/g.

22. The sputtering target according to claim 16, being formed as a tubular sputtering target.

23. The sputtering target according to claim 16, being formed as a planar sputtering target.

24. The sputtering target according to claim 16, comprising a proportion by area of the W phase measured at a cross section of a target material in a range from 5% to 50%.

25. The sputtering target according to claim 16, wherein the W phase has an average grain size of less than 40 μm.

26. A method for producing a WNiX sputtering target by a powder-metallurgical process, the method comprising:
in a compaction step, producing a blank for the sputtering target by compacting a powder mixture of a tungsten (W) powder, a nickel (Ni) powder, and a powder of a further metal X selected from group 5 or group 6 of the periodic table, by applying to the powder mixture pressure, heat, or pressure and heat to produce the blank.

27. The method for producing the WNiX sputtering target according to claim 26, wherein the compaction step comprises sintering at temperatures from 1100 to 1450°C.

28. The method for producing a WNiX sputtering target according to claim 26, further comprising a forming step subsequent to the compaction step.

29. The method according to claim 28, wherein the forming step comprises rolling or forging.

30. The method according to claim 28, which comprises heat treating the sputtering target after the forming step.
